(19) United States
(12) Patent Application Publication
(10) Pub. No.: US 2021/0048864 A1
(43) Pub. Date: Feb. 18, 2021

(54) DEVICE FOR LINKING AT LEAST TWO ELECTRONIC APPARATUSES

(71) Applicant: Danfoss S.r.l, Burgstall (IT)

(72) Inventors: Martin Reifer, Burgstall (IT); Patrice Rollin, Burgstall (IT); René Daniel Linser, Burgstall (IT)

(21) Appl. No.: 16/991,360

(22) Filed: Aug. 12, 2020

(30) Foreign Application Priority Data
Aug. 14, 2019 (DE) 102019121914.0

(51) Int. Cl. G06F 1/26; G06F 1/18

(52) U.S. Cl. CPC G06F 1/266; G06F 1/189; G06F 1/188

(57) ABSTRACT

The invention relates to a device (10) for linking at least two electronic apparatuses (60), the device (10) comprising a first power supply connector (12), a first DC link connector (16), a second power supply connector (14), a second DC link connector (18), and an electronic apparatus connector (20), wherein the electronic apparatus connector (20) comprises power supply lines (24) and DC lines (22), wherein the first power supply connector (12) is electrically connected to the second power supply connector (14) and the power supply lines (24), wherein the first DC link connector (16) is electrically connected to the second DC link connector (18) and the DC lines (22), wherein the first power supply connector (12) is pluggable to a second power supply connector (14) of a further device (10) for linking at least two electronic apparatuses (60), wherein the first DC link connector (16) is pluggable to a second DC link connector (18) of a further device (10) for linking at least two electronic apparatuses (60). The invention provides an improved device (10) for linking at least two electronic apparatuses (60), wherein the device (10) is more flexible and has a simplified handling.

### CROSS-REFERENCE TO RELATED APPLICATION

This application claims foreign priority benefits under 35 U.S.C. § 119 to German Patent Application No. 102019121914.0 filed on Aug. 14, 2019, the content of which is hereby incorporated by reference in its entirety.

### TECHNICAL FIELD

The invention relates to a device for linking at least two electronic apparatuses.

### BACKGROUND

Modular electronic apparatuses like modular frequency converters, servo drives and any other electronic apparatus may be connected via DC link buses and electrical auxiliary power supply buses, which are either cut on length or which are screwed together. The DC link bus and the auxiliary power supply bus may be provided by a combined bus system. The bus system may be any kind of bus system, for example, a data bus system, control bus system, power bus system, auxiliary bus system. For adapting the buses to the number of electronic apparatuses to be connected, the buses may be cut on length or may be produced from bus modules, which are screwed together.

The length of the buses, which are cut on length, is determined by the manufacturer. The manufacturer cuts the bus bars on length and adds the number required connectors. A later increase of the number of electronic apparatuses re-quires a replacement of the bus by a newly adapted bus.

The buses, which are screwed together, comprise bus bar modules, which are screwed together with a predecessor bus bar module and, if required, with a successor bus bar module.

### SUMMARY

The technical object may be providing an improved device for linking at least two electronic apparatuses, wherein the device is more flexible and has a simplified handling.

Claims 1 and 14 indicate the main features of the invention. Features of embodiments of the invention are subject of claims 2 to 13.

In an aspect of the invention, a device for linking at least two electronic apparatuses is provided, the device comprising a first power supply connector, a first DC link connector, a second power supply connector, a second DC link connector, and an electronic apparatus connector, wherein the electronic apparatus connector comprises power supply lines and DC lines, wherein the first power supply connector is electrically connected to the second power supply connector and the power supply lines, wherein the first DC link connector is electrically connected to the second DC link connector and the DC lines, wherein the first power supply connector is pluggable to a second power supply connector of a further device for linking an electronic apparatus to another electronic apparatus, wherein the first DC link connector is pluggable to a second DC link connector of a further device for linking the electronic apparatus to the other electronic apparatus.

The invention provides a device for linking at least two electronic apparatuses, wherein the device has a pluggable connection to a further device. Each device provides an electronic apparatus connector. The number of the connected devices for linking electronic apparatuses therefore determines the number of electronic apparatuses that may be connected. The device for linking at least two electronic apparatuses is a module of a DC link bus and/or a power supply bus, wherein the DC link bus and power supply bus may comprise a single module, i.e. a single device for linking at least two electronic apparatuses. For the connection between the devices for linking an electronic apparatus to an electrical system, the first DC link connector of the device for linking at least two electronic apparatuses may be plugged into the second DC link connector of a further device for linking at least two electronic apparatuses, which is already connected to the bus. Furthermore, the first power supply connector of the device for linking at least two electronic apparatuses may be plugged into the second power supply connector of the further device for linking at least two electronic apparatuses, which is already connected to the bus. Alternatively or additionally, the second DC link connector of the device for linking at least two electronic apparatuses may be plugged into the first DC link connector of a further device for linking at least two electronic apparatuses, which is already connected to the bus. Furthermore, the second power supply connector of the device for linking at least two electronic apparatuses may be plugged into the first power supply connector of the further device for linking at least two electronic apparatuses, which is already connected to the bus. The electrical power provided by the second power supply connector of the further device is then provided via the first power supply connector of the device to the electronic apparatus connector and the second power supply connector of the device. It is also possible that the electrical power is provided by the first power supply connector of the further device via the second power supply connector of the device to the electronic apparatus connector and the first power supply connector of the device. Furthermore, the second DC link connector of the further device provides a DC link via the first DC link connector of the device to the electronic apparatus connector and the second DC link connector of the device. It is also possible that the first DC link connector of the further device provides a DC link via the second DC link connector of the device to the electronic apparatus connector and the first DC link connector of the device. The first DC link connector and the first power supply connector of further device may be connected to the second DC link connector and the second power supply connector of the device. For each electronic apparatus, which shall be linked to the bus, a further device is connected to the previous devices. The second DC link connector and the second power supply connector of one device are plugged to the first DC link connector and the first power supply connector of a further device, respectively, such that the devices are fixed together. Based on this pluggable concept, the invention allows flexibly varying the length of the DC link bus and power supply bus. Furthermore, it allows easily connecting the electronic apparatuses to the DC link bus and power supply bus without the need of any tool or screw.

The first power supply connector, the first DC link connector, the second power supply connector, the second DC link connector, and the electronic apparatus connector may be multi-pin connectors.

The first power supply connector, the first DC link connector, the second power supply connector, the second DC link connector, and the electronic apparatus connector may be a single connector, e.g. a three-way bidirectional connector. The first power supply connector and the first DC link connector may be a combined first connector. Furthermore, the second power supply connector and the second DC link connector may be a combined second connector.

The first and second power supply connector may be a plug and a socket, which provide a pluggable connection between each other. Furthermore, the first and second DC link connector may be a plug and a socket, which provide a pluggable connection between each other.

Furthermore, the device for linking at least two electronic apparatuses may be a module of a bus.

In an example, the first power supply connector and the first DC link connector face away from the second power supply connector and the second DC link connector.

The first power supply connector may therefore connect to a further device being on one side of the device, wherein the second power supply connector may be on the other side of the device. Furthermore, the first DC link connector may therefore connect to a further device being arranged on one side of the device, wherein the second DC link connector may be arranged on the other side of the device. The device may therefore connect to a further device on both sides. If two further devices connect to the device, the device is arranged between the two further devices.

The device may further comprise a first surface and a second surface facing away from each other, wherein the first power supply connector and the first DC link connector are arranged on the first surface or the second surface, wherein the second power supply connector and the second DC link connector are arranged on the other one of the first surface and the second surface. However, this does not exclude an exemplary embodiment with a first surface and a second surface, which do not face away from each other. The first surface and the second surface may be arranged parallel.

The further device being connected to the connectors on the first surface may therefore be a predecessor device, wherein another device being connected to the connectors on the second surface may be a successor device.

Furthermore, the device may comprise an electronic apparatus receiving surface extending between or including the first surface and a second surface, wherein the electronic apparatus connector is arranged on the electronic apparatus surface.

The electronic apparatus connector may therefore face in a direction, which is different from the facing directions of the first and second power supply connectors and DC link connector. In an example, the electronic apparatus connector is arranged in a direction being orthogonal to the arrangement direction of the first and second power supply connectors and DC link connectors. However, this does not exclude an exemplary embodiment with an electronic apparatus connector, a first and second power supply connectors and DC link connector, which do not face away from each other. For example, the electronic apparatus connector, the first and second power supply connectors and DC link connector may be arranged parallel.

In a further example, the electronic apparatus connector may comprise a plug that is pluggable to a socket of an electric connector of an electronic apparatus.

An electric connector of an electronic apparatus may therefore connect to the electronic apparatus connector in a pluggable manner. That pluggable connection provides a fixed connection between the device and the electronic apparatus. Screws are not required for connecting the electronic apparatus to the device. This simplifies the connection process between the electronic apparatus and the device. Furthermore, the electronic apparatus may be easily replaced without using screws. Hence, the handling of the device is further simplified.

The device may further comprise a plate element for receiving a surface of an electronic apparatus, the plate element extending away from the first power supply connector, the first DC link connector, the second power supply connector, the second DC link connector, and the electronic apparatus connector.

The plate element may be configured to cover a complete surface of the electronic apparatus, wherein that complete surface comprises an electric connector of the electronic apparatus being connectable to the electronic apparatus connector of the device. Furthermore, the plate element may comprise the electronic apparatus receiving surface.

Furthermore, the device may comprise a locking mechanism for locking a connection between the electronic apparatus connector and an electric connector of the electronic apparatus being connected to the electronic apparatus connector.

By locking the connection between the device and the electronic apparatus, the locking mechanism improves the safety of the connection and the mounting of the electronic apparatus on the bus being established by the device.

The locking mechanism may further comprise a lever element that is pivotally mounted on the device, wherein, in a locking position, the lever element locks the electronic apparatus being connected to the electronic apparatus connector, wherein in an opening position of the lever element the electronic apparatus is detachable from the electronic apparatus connector.

The lever element provides an easy handling of the locking mechanism when connecting or disconnecting an electronic apparatus to the device. The lever element may lock the electronic apparatus to the device by form fit.

The device may further comprise a first locking element and a second locking element, wherein the first locking element is configured to connect to a second locking element of a further device for linking at least two electronic apparatuses, if the first DC link connector and the first power supply connector are connected to a second DC link connector and a second power supply connector of the further device, and wherein the second locking element is configured to receive a first locking element of a further device for linking at least two electronic apparatuses, if the second DC link connector and the second power supply connector are connected to a first DC link connector and a first power supply connector of a further device.

By using the first locking element and second locking element, the device may be fixed to another device when a power supply connection or a DC link connection is established between the device and the other device. The bus being established by the devices may then be easily stabilized and handled.

Furthermore, the first locking element may comprise a hook element, wherein the second locking element comprises a hook recess for receiving a hook element.

The device may therefore be locked to another device by a hook connection. The hook element of one device is hooked into the hook recess for receiving the hook element of the other device. Thus, the devices may be easily connected. The hook and the hook recess for receiving the hook element may be arranged on the plate element.

In a further example, the device may comprise a support and guide element for guiding an electric connector of an electronic apparatus to the electronic apparatus connector.

The support and guide element guides the electronic apparatus such that the electric connector of the electronic apparatus automatically connects to the electronic apparatus connector of the device. This simplifies the mounting process of the electronic apparatus on the device.

The support and guide element may further comprise a stub element for receiving a stub recess of an electronic apparatus and providing a pivot axis for the electronic apparatus, if the stub recess is connected to the stub element.

The electronic apparatus may be connected to the support and guide element by receiving the stub element in the stub recess. When the electronic apparatus connects to the support and guide element, the electronic apparatus may be turned around the pivot axis. The turn automatically arranges the electric connector of the electronic apparatus on the electronic apparatus connector of the device.

The device may comprise at least one bore for a fixation element, preferably a screw, for fixing the device on an external frame.

The bore may for example be arranged on the plate element. The device may be attached to the frame via fixation elements, which extend through the bores.

In a further aspect, a system for connecting a plurality of electronic apparatuses is provided, the system comprising at least two devices according to the preceding description, wherein the second power supply connector and the second DC link connector of one of the at least two devices are connected to the first power supply connector and the first DC link connector of another of the at least two devices.

The effects and further embodiments of the system according to the present invention are analogous to the effects and embodiments of the device according to the description mentioned above. Thus, it is referred to the above description of the device.

### BRIEF DESCRIPTION OF THE DRAWINGS

Further features, details and advantages of the invention result from the wording of the claims as well as from the following description of exemplary embodiments based on the drawings. The figures show:

FIG. 1 a schematic drawing of a device for linking at least two electronic apparatuses;

FIG. 2 a schematic drawing of the electrical lines of the device;

FIG. 3 a schematic drawing of a system for connecting a plurality of electronic apparatuses;

FIG. 4a, b a schematic drawing of a guiding element;

FIG. 5 a schematic drawing of a locking mechanism; and

FIG. 6 a schematic drawing of another example of the device.

### DETAILED DESCRIPTION

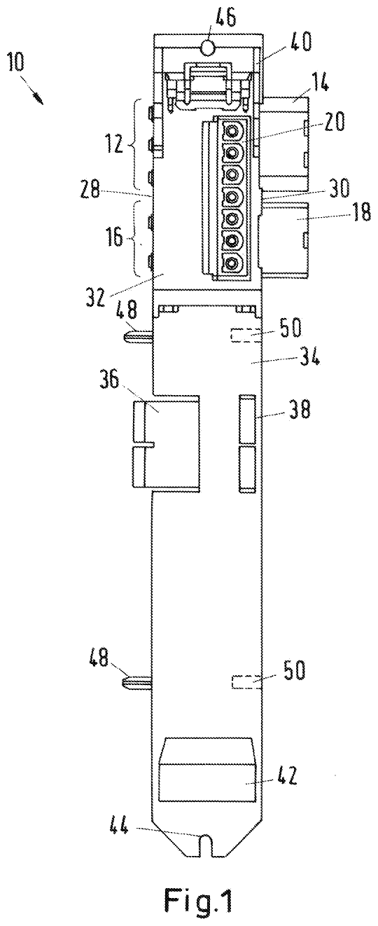

FIG. 1 shows a device for linking at least two electronic apparatuses, wherein the device in its entirety is denoted with the reference sign 10.

The device 10 comprises a first power supply connector 12, a second power supply connector 14, a first DC link connector 16, a second DC link connector 18, and an electronic apparatus connector 20. The first power supply connector 12 and the first DC link connector 16 are arranged on a first surface 28 of the device 10. The second power supply connector 14 and the second DC link connector 18 are arranged on a second surface 30 of the device 10. In the shown example according to FIG. 1, the first surface 28 and the second surface 30 face away from each other. However, the first surface 28 and the second surface 30 may also be arranged such that they do not face away from each other.

Furthermore, the first power supply connector 12 is pluggable to a second power supply connector 14 of a further device 10 for linking an electronic apparatus to another electronic apparatus. The second power supply connector 14 is pluggable to a first power supply connector 12 of another further device 10 for linking the electronic apparatus to the other electronic apparatus.

In addition, the first DC link connector 16 is pluggable to a second DC link connector 18 of the further device 10, and the second DC link connector 18 is pluggable to a first DC link connector 16 of the other further device 10.

The electronic apparatus connector 20 is further pluggable to an electric connector of an electronic apparatus.

The pluggable connection of the connectors mentioned above means that the connection may be fixed by a frictional connection and/or a form fit connection between the connectors. Furthermore, the pluggable connection is detachable. Screws are not required for connecting the connectors mentioned above.

The electronic apparatus connector 20 is arranged on an electronic apparatus receiving surface 32. The electronic apparatus receiving surface 32 extends between the first surface 28 and the second surface 30 of the device 10. Furthermore, the electronic apparatus receiving surface 32 faces in another direction than the first surface 28 and the second surface 30. Particularly, the electronic apparatus receiving surface 32 may face orthogonally with respect to the first surface 28 and the second surface 30.

The device 10 further comprises the plate element 34 for receiving the surface of an electronic apparatus. The plate element 34 extends away from the device 10. Particularly, the plate element 34 extends away from the region in which the first power supply connector 12, the second power supply connector 14, the first DC link connector 16, the second DC link connector 18 and the electronic apparatus connector 20 are arranged.

The plate element 34 may comprise a locking mechanism 40 for locking a connection between an electronic apparatus connector 20 and an electric connector of an electronic apparatus being connected to the electronic apparatus connector 20. The locking mechanism 40 may comprise a lever element that is pivotally mounted on the device 10. The lever element comprises a locking position and an opening position. In the locking position, the lever element locks the electronic apparatus on the device 10 when the electric connector 58 of the electronic apparatus connects to the electronic apparatus connector 20. The electronic apparatus comprises a pin, which may connect to the lever element in the locking position. The connection between the lever element and the pin may be a form fit. In the opening position, the lever element is detached from the electronic apparatus. The electronic apparatus may then be detached from the device 10.

Furthermore, the plate element 34 may comprise a first locking element 36 and a second locking element 38. The first locking element 36 is configured to connect to a second locking element 38 of a further device 10 for linking at least two electronic apparatuses. The second locking element 38 is configured to receive a first locking element 36 of the further device 10 for linking at least two electronic apparatuses if the second DC link connector 18 and the second power supply connector 14 are connected to a first DC link connector 16 and a first power supply connector 12 of the further device 10. The first locking element 36 may comprise a hook element 36 and the second locking element 38 may comprise a hook recess 38. The hook element 36 of the device 10 may be connectable to a hook recess 38 of a further device 10 that is connected to the first power supply connector 12 and the first DC link connector 16 of the device 10. The hook recess 38 of the device 10 may receive a hook element 36 of another further device 10, which is connected to the second power supply connector 14 and the second DC link connector 18 of the device 10. The connection between the hook element 36 of the device 10 and the hook recess 38 of the further device 10 may be provided by form fit. For connecting the hook element 36 of the device 10 to the hook recess 38 of the further device 10, the hook element 36 is put into the hook recess 38 of the further device 10. This automatically takes place when the second power supply connector 14 and the second DC link connector 18 of the further device 10 receive the first power supply connector 12 and the first DC link connector 16 of the device 10. The hook element 36 of the device 10 may be detachable from the hook recess 38 of the further device 10 by bending the hook element 36 out of the hook recess 38.

Furthermore, the plate element 34 may comprise a support and guide element 42 for guiding an electric connector of the electronic apparatus to the electronic apparatus connector 20. The support and guide element 42 may comprise a stub element 52 providing a pivot axis for rotating the electronic apparatus if a stub recess of the electronic apparatus receives the stub element 52. The electronic apparatus may then be rotated around the pivot axis such that the electric connector of the electronic apparatus is plugged into the electronic apparatus connector 20. Furthermore, the support and guide element 42 may provide a supporting and fixing function between the connected electronic apparatuses.

Pin elements 48 and bushing elements 50 may be arranged on the plate element 34. The pin elements 48 may be arranged on a side of the plate element 34 being opposite to the side of the bushing elements 50 on the plate element 34. Thus, the pin elements 48 may face in an opposite direction than the bushing elements 50. For example, the pin elements 48 may be arranged on the device 10 on the same side as the first surface 28, wherein the bushing elements 50 may be arranged on the device 10 on the same side as the second surface 30. The pin elements 48 of the device 10 may be configured to connect to bushing elements 50 of a further device 10, wherein the second power supply connector 14 and the second DC link connector 18 of the further device 10 are connected to the first power supply connector 12 and the first DC link connector 16 of the device 10. Furthermore, the bushing elements 50 of the device 10 may be configured to receive pin elements 48 of another further device 10, wherein the first power supply connector 12 and the first DC link connector 16 of the other further device 10 may be connected to the second power supply connector 14 and the second DC link connector 18 of the device 10.

The device 10 further comprises bores 44, 46, which are adapted to receive fixation elements. The fixation elements may mount the device 10 on a frame for holding the bus with the electronic apparatuses.

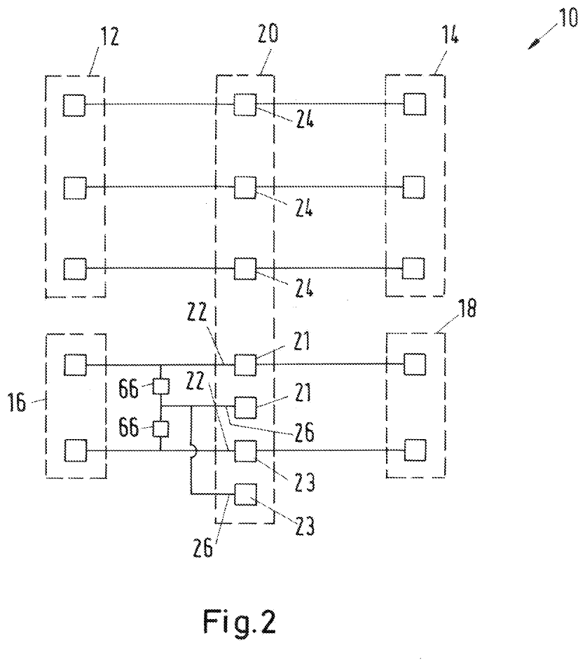

FIG. 2 shows the electrical connection lines between the connectors of the device 10. The electronic apparatus connector 20 comprises power supply lines 24 and DC lines 22. The power supply lines 24 are attached to electrical pins of the electronic apparatus connector 20, which provide auxiliary electrical power. The DC lines 22 are attached to electrical pins of the electronic apparatus connector 20, which provide DC voltage. The first power supply connector 12 is electrically connected to the power supply lines 24 and the second power supply connector 14. The first DC link connector 16 is electrically connected to the DC lines 22 and the second DC link connector 18.

The electronic apparatus connector 20 according to FIG. 2 comprises two sub connectors for the DC voltage. A first pair 21 of sub connectors provides a positive DC voltage wherein the second pair 23 of connectors provides a negative DC voltage. Each pair comprises a pin, which is connected to an electrical line, which provides an electrical potential between the electrical potentials of the DC lines 22 being attached to the first DC link connector 16. This may for example be achieved by a voltage divider comprising the resistors 66 shown in FIG. 2. Due to the splitting of the DC current to the two sub connectors for the DC voltage, only half of the DC current flows through each sub connector. Thus, the DC current that can flow through the device 10 can be higher than the maximum DC current that is allowed for one sub connector.

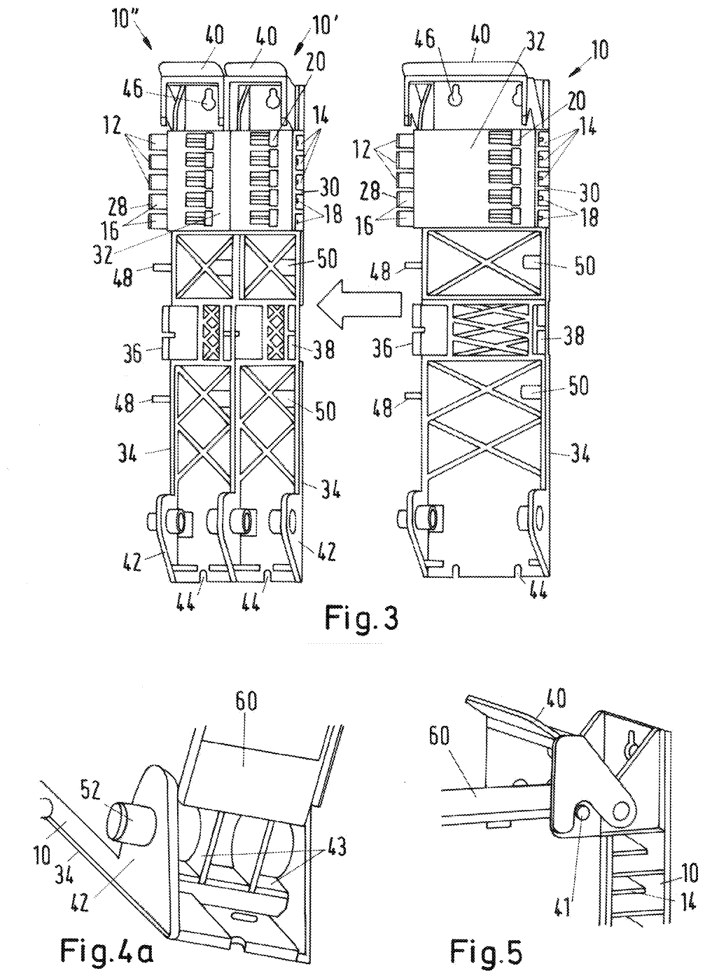

FIG. 3 shows the connection of a device 10 for linking an electronic apparatus 60 to an electrical system to a further device 10′. The further device 10′ is already connected to another further device 10″. The device 10′ and the device 10″ determine a bus. The device 10 is moved in the direction of the arrow shown in FIG. 3 to connect to device 10′. The first power supply connectors 12 and the first DC link connectors 16 of the device 10 are moved into the second power supply connectors 14 and the second DC link connectors 18 of the further device 10′. The hook element 36 of the device 10 automatically hooks into the hook recess 38 of the further device 10′ when the connection between the first and second connectors of the devices 10, 10′ is established. Furthermore, the pin elements 48 of the device 10 are moved into the bushing elements 50 of the further device 10′ to stabilize the connection between the device 10 and the further device 10′.

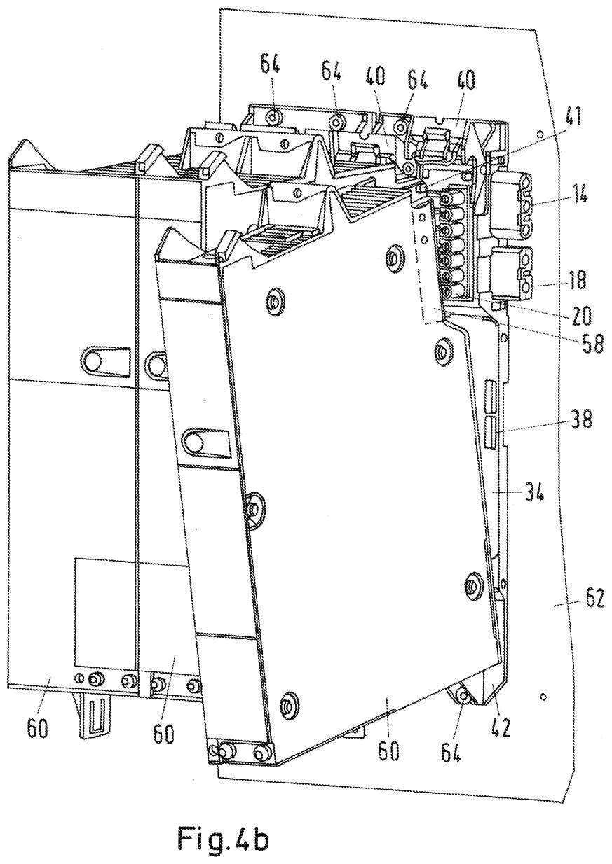

FIGS. 4a and 4b show the support and guide element 42 in further detail. FIG. 4a shows the support and guide element 42 of the device 10 and a guide recess 43 of an electronic apparatus 60. The support and guide element 42 comprises a stub element 52. The guide recess 43 receives the stub element 52. The device 10 may comprise two stub elements 52 which are arranged on opposite sides of the device 10. A clearance is arranged between the stub elements 52. The electronic apparatus 60 further comprises to stub recesses 43 facing away from each other. The electronic apparatus 60 is arranged in the clearance between the stub elements 52 for arranging the stub recesses 43 on the stub elements 52. The stub element 52 provides a pivot axis for the electronic apparatus 60, which receives the stub element 52. The electronic apparatus 60 may then be rotated around the pivot axis, as shown in FIG. 4b. That rotational movement places the electric connector of the electronic apparatus 60 on the electronic apparatus connector of the device 10. The turning further connects the electric connector and the electronic apparatus connector.

FIG. 4b further shows a plurality of electronic apparatuses 60, which are connected to a plurality of devices 10 for linking an electronic apparatus 60 to the electrical system. The devices 10 comprise bores which are configured to receive fixation elements 64 to connect the devices 10 to a frame 62.

When the electric connector 58 of the electronic apparatus 60 is connected to the electronic apparatus connector 20 of the device 10, the locking mechanism 40 may lock the electronic apparatus 60 on the device 10 such that the electric connector 58 of the electronic apparatus 60 is locked at the electronic apparatus connector 20 as shown in FIG. 5. The locking mechanism 40 comprises a lever element which is pivotally attached to the device 10. In the locking position, the lever element is in form fit with a pin 41 on the electronic apparatus 60 to lock the electronic apparatus 60 on the device 10. The lever element may be pivoted around a lever axis between an opening position and a locking position. In the opening position the lever element does not lock the electronic apparatus 60 to the device 10.

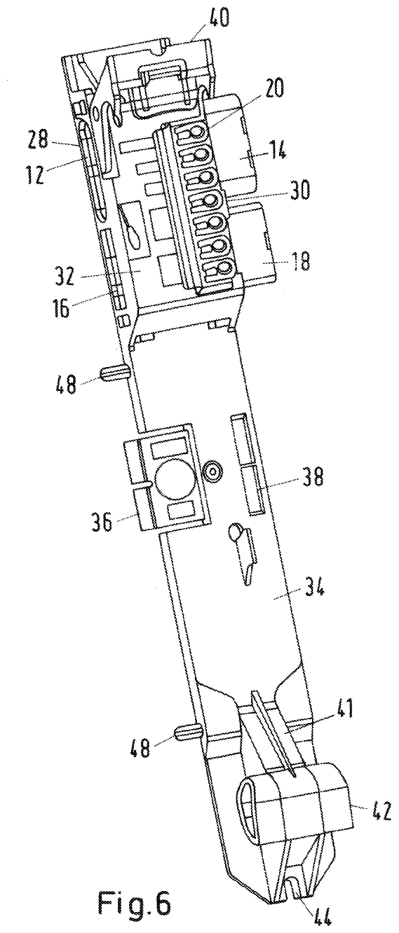

FIG. 6 shows a further example of the device 10. The bores 44 may be arranged at any position on the device 10. A further bore 44 is arranged at a bottom end of the device 10. Furthermore, the two stub elements 52 may be arranged such that they face away from each other. They may further be arranged on a common connection 41 to the device 10. Consequently, the electronic apparatus 60 which shall be attached to the device 10 comprises a central recess for receiving the stub elements 52.

The invention is not limited to one of the aforementioned embodiments. It can be modified in many ways.

All features and advantages resulting from the claims, the description and the drawing, including constructive details, spatial arrangements and procedural steps, may be essential for the invention both in themselves and in various combinations.

What is claimed is:

1. A device for linking an electronic apparatus to an electrical system, the device comprising a first power supply connector, a first DC link connector, a second power supply connector, a second DC link connector, and an electronic apparatus connector, wherein the electronic apparatus connector comprises power supply lines and DC lines, wherein the first power supply connector is electrically connected to the second power supply connector and the power supply lines, wherein the first DC link connector is electrically connected to the second DC link connector and the DC lines, wherein the first power supply connector is pluggable to a second power supply connector of a further device for linking at least two electronic apparatuses, wherein the first DC link connector is pluggable to a second DC link connector of a further device for linking at least two electronic apparatuses.

2. The device according to claim 1, wherein the first power supply connector and the first DC link connector face away from the second power supply connector and the second DC link connector.

3. The device according to claim 1, wherein the device comprises a first surface and a second surface facing away from each other, wherein the first power supply connector and the first DC link connector are arranged on the first surface or the second surface, wherein the second power supply connector and the second DC link connector are arranged on the other one of the first surface and the second surface.

4. The device according to claim 3, wherein the device further comprises an electronic apparatus receiving surface extending between or including the first surface and a second surface, wherein the electronic apparatus connector is arranged on the electronic apparatus receiving surface.

5. The device according to claim 1, wherein the electronic apparatus connector comprises a plug that is pluggable to an electronic apparatus connector socket of an electronic apparatus.

6. The device according to claim 1, wherein the device further comprises a plate element for receiving a surface of an electronic apparatus, the plate element extending away from the first power supply connector, the first DC link connector, the second power supply connector, the second DC link connector, and the electronic apparatus connector.

7. The device according to claim 1, wherein the device further comprises a locking mechanism for locking a connection between the electronic apparatus connector and an electronic apparatus being connected to the electronic apparatus connector.

8. The device according to claim 7, wherein the locking mechanism comprises a lever element that is pivotally mounted on the device, wherein in a locking position the lever element locks the electronic apparatus being connected to the electronic apparatus connector, wherein in an opening position of the lever element the electronic apparatus is detachable from the electronic apparatus connector.

9. The device according to claim 1, wherein the device further comprises a first locking element and a second locking element, wherein the first locking element is configured to connect to a second locking element of a further device for linking at least two electronic apparatuses, if the first DC link connector and the first power supply connector are connected to a second DC link connector and a second power supply connector of the further device, and wherein the second locking element is configured to receive a first locking element of a further device for linking at least two electronic apparatuses, if the second DC link connector and the second power supply connector are connected to a first DC link connector and a first power supply connector of the further device.

10. The device according to claim 9, wherein the first locking element comprises a hook element, wherein the second locking element is a hook recess for receiving a hook element.

11. The device according to claim 1, wherein the device comprises a support and guide element for guiding an electric connector of an electronic apparatus to the electronic apparatus connector.

12. The device according to claim 11, wherein the support and guide element comprises a stub element for receiving a stub recess of an electronic apparatus and providing a pivot axis for the electronic apparatus, if the stub recess is connected to the stub element.

13. The device according to claim 1, wherein the device comprises at least one bore for a fixation element, preferably a screw, for fixing the device on an external frame.

14. A system for connecting a plurality of electronic apparatuses, the system comprising at least two devices according to claim 1, wherein the second power supply connector and the second DC link connector of one of the at least two devices are connected to the first power supply connector and the first DC link connector of another of the at least two devices.

15. The device according to claim 2, wherein the device comprises a first surface and a second surface facing away from each other, wherein the first power supply connector and the first DC link connector are arranged on the first surface or the second surface, wherein the second power supply connector and the second DC link connector are arranged on the other one of the first surface and the second surface.

16. The device according to claim 2, wherein the electronic apparatus connector comprises a plug that is pluggable to an electronic apparatus connector socket of an electronic apparatus.

17. The device according to claim 3, wherein the electronic apparatus connector comprises a plug that is pluggable to an electronic apparatus connector socket of an electronic apparatus.

18. The device according to claim 4, wherein the electronic apparatus connector comprises a plug that is pluggable to an electronic apparatus connector socket of an electronic apparatus.

19. The device according to claim 2, wherein the device further comprises a plate element for receiving a surface of an electronic apparatus, the plate element extending away from the first power supply connector, the first DC link connector, the second power supply connector, the second DC link connector, and the electronic apparatus connector.

20. The device according to claim 3, wherein the device further comprises a plate element for receiving a surface of an electronic apparatus, the plate element extending away from the first power supply connector, the first DC link connector, the second power supply connector, the second DC link connector, and the electronic apparatus connector.
